(19) United States
(12) Patent Application Publication
(10) Pub. No.: US 2023/0070841 A1
(43) Pub. Date: Mar. 9, 2023

(54) Cantilever For A Piezoelectric Energy Harvesting System

(71) Applicant: UAB Nanoenergija, Varena (LT)

(72) Inventors: Vytautas MARKEVICIUS, Kaunas (LT); Donat PONAMARIOV, Vilnius (LT)

(73) Assignee: UAB Nanoenergija, Vilnius (LT)

(21) Appl. No.: 17/801,244

(22) PCT Filed: Jul. 30, 2020
(86) PCT No.: PCT/EP2020/071552

§ 371 Date: Aug. 20, 2022

(51) Int. Cl. H02N 2/18; H01L 41/083; H01L 41/113; H01L 41/193; H01L 41/047

(52) U.S. Cl. CPC H02N 2/188; H01L 41/083; H01L 41/1136; H01L 41/193; H01L 41/0477

(57) ABSTRACT

The present invention relates to a cantilever for a piezoelectric energy harvesting system, wherein the cantilever (2,20,30) comprises two layers (21,22,31,32) formed of polyvinylidene fluoride, and wherein a core layer (23,33) formed of a shim material is sandwiched between the two layers (21,22,31,32) formed of polyvinylidene fluoride

The present application relates to a cantilever for an energy harvesting system and, in particular, to an improved cantilever for a piezoelectric energy harvesting system.

There are many unutilized energy sources in the environment, for example, thermal energy, electromagnetic waves, and mechanical vibrations. To convert these ambient energies into electric energy, energy harvesting technologies have been developed. Energy harvesting technologies can, for example, be used as an energy source for a battery of a wireless sensor. There are further various energy sources for energy harvesting such as solar power, thermal energy, wind power, and vibration. Further, there are three main types of vibration energy harvesters generation methods: electromagnetic, electrostatic, and piezoelectric.

Therein, energy harvesting technology using piezoelectric materials is one such method that utilizes mechanical energy from various sources such as human motion, acoustic noise, or wind to convert energy into an electric current. When mechanical energy such as an acoustic wave is applied to a piezoelectric polymer film, electrical charges are induced between the two surfaces. Using this property, a piezoelectric material can be applied as an electromechanical energy converter.

The document U.S. Pat. No. 7,649,305 B2 discloses a mechanism for capturing mechanical energy and converting it to electrical energy for use in continually charging or providing emergency power to mobile, battery-powered devices, which comprises a plurality of elongated piezoelectric elements mounted at one or more support points to one or more support structures. The plurality of piezoelectric elements are preferably structured and arranged so that at least each three-dimensional coordinate axis has at least one element with a dominant mode of deflection in a plane normal to the axis, to permit harvesting energy from forces applied in any direction without regard to the orientation of the energy harvesting mechanism to the source of forces.

Among piezoelectric materials, respectively polymers which have strong piezoelectric effects when subjected to mechanical stretching or external excitation, polyvinylidene fluoride (PVDF) films have a comparatively high piezoelectric effect and are, at the same time, cheap and easy to manufacture, chemically inert, lightweight and safe to us. However, as these films are usually very thin, polyvinylidene fluoride films are usually not used as a basis for piezoelectric energy harvesting systems due to their fragility and the very short response times.

It is an object of the present invention to provide an improved cantilever for a piezoelectric energy harvesting system.

According to one embodiment of the invention, a cantilever for a piezoelectric energy harvesting system is provided, wherein the cantilever comprises two layers formed of polyvinylidene fluoride, and wherein a core layer formed of a shim material is sandwiched between the two layers formed of polyvinylidene fluoride.

Therefore, a cantilever for a piezoelectric energy harvesting system is provided, which is based on polyvinylidene fluoride films. Thus, it can be taken full advantage of the use of polyvinylidene fluoride as a piezoelectric material, and, in particular, that polyvinylidene fluoride films have a comparatively high piezoelectric effect and are, at the same time, cheap and easy to manufacture, chemically inert, lightweight and safe to us. On the other hand, however, the problems that usually arise when a cantilever for a piezoelectric energy harvesting system should be based on polyvinylidene fluoride films can be neglected, due to the configuration of the cantilever. For example, the fragility of the cantilever based on polyvinylidene fluoride can be reduced by placing a core layer formed of a shim material between the two layers formed of polyvinylidene fluoride. Therefore, an improved cantilever for a piezoelectric energy harvesting system is provided.

Therein, the two layers formed of polyvinylidene fluoride can have a predominantly β-type crystal structure. Polyvinylidene fluoride has four crystalline phases α, β, γ, and δ depending on the chain conformation. Among them, a is thermodynamically the most stable and nonpolar innature. β and γ are polar phases, wherein crystalline phase β is of great importance due to its spontaneous polarization and piezoelectric sensitivity. Thus, the cantilever can be further improved when the two layers formed of polyvinylidene fluoride have a predominantly β-type crystal structure.

Further, the cantilever can have the form of a rectangular plate, wherein the longitudinal sides of the rectangular plate are longer than the broadsides of the rectangular plate, and wherein the cantilever (is configured in such a way, that the cantilever can be connected to a device which stores or uses energy via one of the longitudinal sides. By configuring the cantilever in such a way, that a longer side of the cantilever can be electrically or electrically and mechanically connected to a device which stores or uses energy, the robustness can be further improved, and therefore, the fragility of the cantilever based on polyvinylidene fluoride be further reduced.

As shim materials, aluminum, steel, brass, and laminated plastic, respectively polyethylene terephthalate (PET) are commonly used.

Therein, according to one embodiment, the core layer can be formed of steel. The use of steel as material for the core layer has the advantage that the cantilever can vibrate in the greatest possible resonance frequency, wherein, at the same time, the vibration wave can be as long as possible.

Further, a core layer formed of steel preferably has a thickness between 50 μm and 150 μm, to achieve the greatest power output.

According to another embodiment, the core layer is formed of polyethylene terephthalate (PET). The use of polyethylene terephthalate as material for the core layer has the advantage that comparatively great power output can be achieved.

Further, a core layer formed of polyethylene terephthalate preferably has a thickness between 400 μm and 560 μm, to achieve the greatest power output.

Further, each of the two layers formed of polyvinylidene fluoride can have a thickness between 20 μm and 50 μm. That the polyvinylidene fluoride layers respectively have a thickness between 20 μm and 50 μm has the advantage, that applied kinetic stress can be converted in a very efficient way. Further, if the layers are too thin there is a potential for migration of extractants through the layers and potential attack from the contents to permeate through the PVDF layers and attack other materials in the construction. Thicker layers would additionally add unnecessary costs.

The two layers formed of polyvinylidene fluoride can respectively be bonded to the core layer by an epoxy resin. By using epoxy resin to secure the polyvinylidene fluoride layers to the core layer, the flexibility of the composition can be enhanced, wherein, at the same time, the risk of breakage of the composition can be further reduced. Furthermore, the use of epoxy resin results in excellent mechanical properties, as well as aging resistance, heat resistance, and corrosion resistance of the composition.

Further, electrodes can be formed on and under each of the two layers formed of polyvinylidene fluoride. By sandwiching the polyvinylidene fluoride layer between two electrodes, a simple, flexible, and compact design is provided capable of producing high volume power densities.

Therein, the electrodes can be formed of aluminum, nickel, or copper. Thus, the electrodes can simply be formed by sputtering metal on the polyvinylidene fluoride film, wherein the metallization of the PDVF film can include aluminum, nickel, or copper, and wherein an electrode can be provided that is more compliant and less susceptible. However, that the electrodes are formed of aluminum, nickel or cooper should merely be understood as an example and other materials can be used for forming the electrodes respectively a metallization on the polyvinylidene fluoride layer, too, for example, chromium, gold, silver, platinum, rhodium, alloys of any of the foregoing, and the like.

According to a further embodiment of the invention, a piezoelectric energy harvesting system is provided, which comprises a cantilever as described above and a device that stores or uses energy, wherein a first end of the cantilever is electrically connected to the device which stores or uses energy.

Therefore, a piezoelectric energy harvesting system is provided, which comprises a cantilever that is based on polyvinylidene fluoride films. Thus, it can be taken full advantage of the use of polyvinylidene fluoride as a piezoelectric material, and, in particular, that polyvinylidene fluoride films have a comparatively high piezoelectric effect and are, at the same time, cheap and easy to manufacture, chemically inert, lightweight and safe to us. On the other hand, however, the problems that usually arise when a cantilever for a piezoelectric energy harvesting system should be based on polyvinylidene fluoride films can be neglected, due to the configuration of the cantilever. For example, the fragility of the cantilever based on polyvinylidene fluoride films can be reduced by placing a core layer formed of a shim material between the two layers formed of polyvinylidene fluoride.

Further, at least one tip mass can be attached to a second end of the cantilever, wherein the second end of the cantilever is opposite the first end. By adding at least one tip weight to a second, free end of the cantilever, the level of vibrations can be increased and the resonance levels controlled.

Therein, a weight of the at least on tip mass can be customized, whereby the resonance frequency of the piezoelectric energy harvesting system can be customized to the real need of the application where it should work.

Furthermore, according to one embodiment, a first tip mass is attached to a top surface of the second end of the cantilever band a second tip mass is attached to a bottom surface of the second end of the cantilever. By placing such an additional mass on a surface of the cantilever opposite to a surface of the cantilever where the first tip mass is placed, a vibration time of the cantilever can be increased. Further, based on the ratio of the weight of the first tip mass to the weight of the second tip mass, the output voltage can be increased.

Embodiments of the invention will now be described with reference to the drawings.

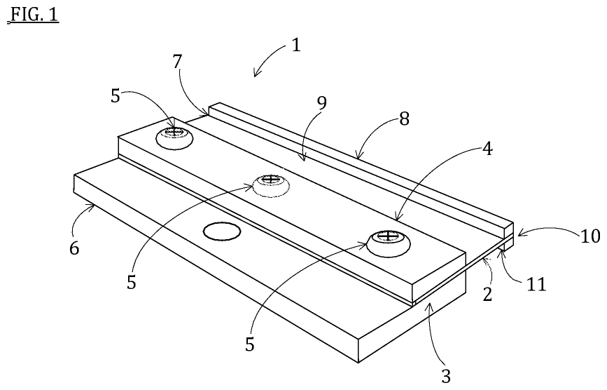

FIG. 1 illustrates a piezoelectric energy harvesting system according to embodiments of the invention;

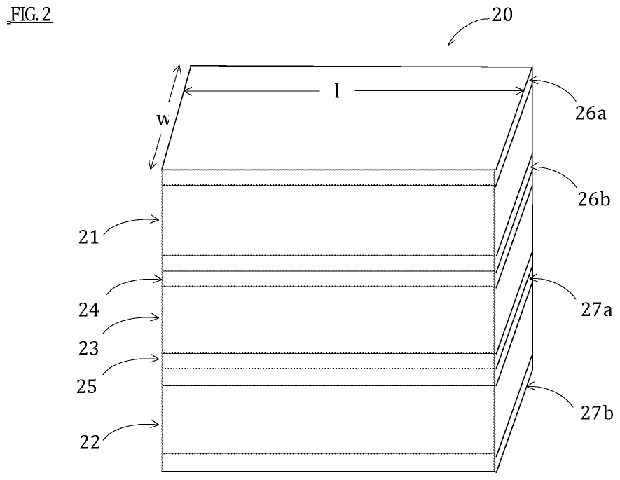

FIG. 2 illustrates a cantilever for a piezoelectric energy harvesting system according to a first embodiment of the invention;

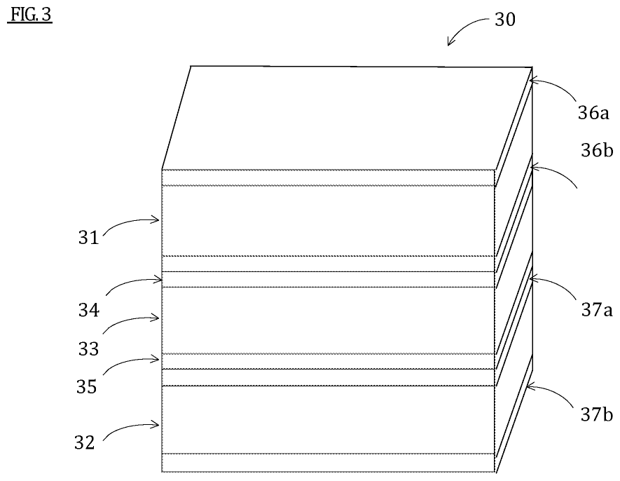

FIG. 3 illustrates a cantilever for a piezoelectric energy harvesting system according to a second embodiment of the invention.

FIG. 1 illustrates a piezoelectric energy harvesting system 1 according to embodiments of the invention.

As shown in FIG. 1, the piezoelectric energy harvesting system 1 comprises a cantilever 2 and a device 3 which stores or uses energy, wherein the device 3 includes a printed circuit board and electronic components, for example, a rectifier unit, a control unit and a storage device, such as a battery and capacitor. Further, a proximal or first end 4 of the cantilever 2 is mechanically and electrically connected to the device 3 which stores or uses energy. According to the embodiments of FIG. 1, the cantilever 2 is anchored into the device 3 and mechanically connected to the device 3 by screws 5. However, the cantilever is mechanically connected to the device by screws should merely be understood as an example and the cantilever can be mechanically connected to the device by other suitable fasteners, too. FIG. 1 further shows a mounting part 6 via which the piezoelectric energy harvesting system can be attached to a device or holding structure.

Piezoelectric energy harvesting systems 1 comprise elements that cause bending, contraction, extraction, etc. in a piezoelectric layer using vibration or pressure and thus generate an alternating current voltage by a piezoelectric effect. Thus, kinetic energy is converted into electrical energy.

These piezoelectric energy harvesting systems 1 are variously applied in that they can use pressure or vibration caused by the exercise of a person, pressure or vibration caused by a vehicle such as a car, and pressure or vibration caused by a natural environment, etc.

Among possible piezoelectric materials, polyvinylidene fluoride (PVDF) films have a comparatively high piezoelectric effect and are, at the same time, cheap and easy to manufacture, chemically inert, lightweight and safe to us. However, as polyvinylidene fluoride films are usually very thin, polyvinylidene fluoride films are usually not used as a basis for piezoelectric energy harvesting systems due to their fragility and the very short response times.

According to the embodiments of FIG. 1, the cantilever 2 comprises two layers formed of polyvinylidene fluoride, wherein a core layer formed of a shim material is sandwiched between the two layers formed of polyvinylidene fluoride.

Therefore, a cantilever 2 for a piezoelectric energy harvesting system 1 is provided, which is based on polyvinylidene fluoride films. Thus, it can be taken full advantage of the use of polyvinylidene fluoride as a piezoelectric material, and, in particular, that polyvinylidene fluoride films have a comparatively high piezoelectric effect and are, at the same time, cheap and easy to manufacture, chemically inert, lightweight and safe to us. On the other hand, however, the problems that usually arise when a cantilever for a piezoelectric energy harvesting system should be based on polyvinylidene fluoride films can be neglected, due to the configuration of the cantilever. For example, the fragility of the cantilever based on polyvinylidene fluoride can be reduced by placing a core layer formed of a shim material between the two layers formed of polyvinylidene fluoride. Therefore, an improved cantilever for a piezoelectric energy harvesting system is provided.

According to the embodiments of FIG. 1, the layers formed of polyvinylidene fluoride are arranged in such a way, that during bending one of the layers (e.g. top layer) is generating the positive charge, whereas the other layer, placed on the opposite side of the core (e.g. bottom layer) also is generating the positive charge, and wherein the two layers are connected in parallel.

In the shown piezoelectric energy harvesting system 1, the level of vibrations amplitude can be increased and the resonance levels controlled by attaching at least one tip mass to a distal or second, free end 7 of the cantilever 2.

Therein, according to the embodiments of FIG. 1, a first tip mass 8 is attached to a top surface 9 of the second end 8 of the cantilever 2, and a second tip mass 10 is attached to a bottom surface 11 of the second end 8 of the cantilever 2. The tip mass 8,10 can, for example, be formed by using a high-density metal such as tungsten, iron, etc.

Further, the first 8 and the second tip mass 10 are configured to be customized to the real need of the application where it should work. For example, in a known application, the first tip mass is chosen to have a weight of 12 g, and the second tip mass is chosen to have a weight of 7 g.

FIG. 2 illustrates a cantilever 20 for a piezoelectric energy harvesting system according to a first embodiment of the invention.

The shown cantilever 20 comprises two layers 21,22 formed of polyvinylidene fluoride, wherein a core layer 23 formed of a shim material is sandwiched between the two layers 21,22 formed of polyvinylidene fluoride.

Therein, the two layers 21,22 formed of polyvinylidene fluoride respectively have a predominantly β-type crystal structure. Each of the two layers 21,22 formed of polyvinylidene fluoride can, for example, be poled to change its phase from α to β by placing the layer under a high electrical field and heating it to a certain temperature, wherein the layer is kept or maintained under the high electrical field for a required amount of time.

Further, the shown cantilever 20 has the form of a rectangular plate, wherein the longitudinal sides of the rectangular plate are longer than the broadsides of the rectangular plate, and wherein the cantilever 20 is configured in such a way, that the cantilever 20 can be connected to a device which stores or uses energy via one of the longitudinal sides.

Therein, each of the layers formed of polyvinylidene fluoride can be prepared in such a way, that it has an approximate length between 60 mm and 80 mm and an approximate width between 10 mm and 20 mm. In particular, according to the embodiments of FIG. 2, each of the polyvinylidene fluoride layers has a length l of 74 mm and a width w of 13 mm. However, that each of the polyvinylidene fluoride layers has a length of 74 mm, and a width of 13 mm should merely be understood as an example, and each of the polyvinylidene fluoride layers can for example also have a length of 64 mm and a width of 12 mm. Further, the stated dimensions are merely examples and the cantilever can have different lengths and widths, too, for example lengths from 10 mm to 150 mm or even more.

According to the first embodiment, the core layer 23 is formed of steel. The use of steel as the material for the core layer has the advantage that the cantilever can vibrate in the greatest possible resonance frequency, wherein, at the same time, the vibration wave can be as long as possible.

Therein, the core layer 23 formed of steel has a thickness between 50 μm and 150 μm, to achieve the greatest power output.

Further, each of the two layers formed of polyvinylidene fluoride has a thickness between 20 μm and 50 μm, to convert the applied kinetic stress in a very efficient way.

As shown in FIG. 2, adhesive layers 24,25 are further formed to respectively secure the layers formed of polyvinylidene fluoride 21,22 to the core layer 23. Therein, an epoxy resin is used to respectively bond the layers 21,22 formed of polyvinylidene fluoride to the core layer 23.

There are further shown layer electrodes 26a,26b,27a,27b which are formed on and under each of the two layers 21,22 formed of polyvinylidene fluoride. These electrodes 26a,26b,27a,27b can be formed to a thickness of several tens to hundreds of nanometers, and can, for example, be formed through a sputtering deposition method.

Further, the electrodes 26a,26b,27a,27b are formed of one of aluminum, nickel, or copper. However, that the electrodes are formed of aluminum, nickel or cooper should merely be understood as an example and other materials can be used for forming the electrodes respectively a metallization on the polyvinylidene fluoride layer, too, wherein the materials for metallization can include chromium, gold, silver, platinum, rhodium, alloys of any of the foregoing, and the like.

FIG. 3 illustrates a cantilever 30 for a piezoelectric energy harvesting system according to a first embodiment of the invention.

As shown in FIG. 3, similar to the cantilever 20 according to the first embodiment, the cantilever 30 according to the second embodiment comprises two layers 31,32 formed of polyvinylidene fluoride, wherein a core layer 33 formed of a shim material is sandwiched between the two layers 31,32 formed of polyvinylidene fluoride, wherein the two layers 31,32 are respectively bonded to the core layer 33 by an adhesive layer 34,35 of epoxy resin, and wherein layer electrodes 36a,36b,37a,37b are formed on and under each of the two layers 31,32 formed of polyvinylidene fluoride.

The difference between the cantilever 30 according to the second embodiment shown in FIG. 3 and the cantilever 20 according to the first embodiment shown in FIG. 2 is that the core layer 33 of the cantilever 30 according to the second embodiment is formed of polyethylene terephthalate (PET), whereby a comparatively great power output can be achieved.

Therein, the core layer 33 formed of polyethylene terephthalate has a thickness between 400 μm and 560 μm, to achieve the greatest power output.

### REFERENCE SIGNS

1 piezoelectric energy harvesting system
2 cantilever
3 device
4 first end
5 screw
6 mounting part
7 second end
8 first tip mass
9 top side
10 second tip mass
11 bottom side
20 cantilever
21 Layer
22 Layer
23 Core layer
24 Adhesive layer
25 Adhesive layer
26a electrode
26b electrode
27a electrode
27b electrode
30 cantilever
31 layer
32 layer
33 core layer
34 adhesive layer
35 adhesive layer
36a electrode
36b electrode
37a electrode
37b electrode
l length
w width

1. Cantilever for a piezoelectric energy harvesting system, wherein the cantilever comprises two layers formed of polyvinylidene fluoride, and wherein a core layer formed of a shim material is sandwiched between the two layers formed of polyvinylidene fluoride, the two layers formed of polyvinylidene fluoride respectively have a predominantly β-type crystal structure.

2. (canceled)

3. Cantilever according to claim 1, wherein the cantilever has the form of a rectangular plate, wherein the longitudinal sides of the rectangular plate are longer than the broadsides of the rectangular plate, and wherein the cantilever is configured in such a way, that the cantilever can be connected to a device which stores or uses energy via one of the longitudinal sides.

4. Cantilever according to claim 3, wherein the core layer is formed of steel.

5. Cantilever according to claim 4, wherein the core layer has a thickness between 50 μm and 150 μm.

6. Cantilever according to claim 3, wherein the core layer is formed of polyethylene terephthalate.

7. Cantilever according to claim 6, wherein the core layer has a thickness between 400 μm and 560 μm.

8. Cantilever according to claim 7, wherein each of the two layers formed of polyvinylidene fluoride has a thickness between 20 μm and 50 μm.

9. Cantilever according to claim 8, wherein the two layers formed of polyvinylidene fluoride are respectively bonded to the core layer by an epoxy resin.

10. Cantilever according to claim 9, wherein electrodes are formed of polyvinylidene fluoride.

11. Cantilever according to claim 10, wherein the electrodes are formed of aluminum, nickel or copper.

12. Piezoelectric energy harvesting system, wherein the system comprises a cantilever according to one of claim 10 and a device which stores or uses energy, and wherein a first end of the cantilever is electrically connected to the device which stores or uses energy.

13. Piezoelectric energy harvesting system according to claim 12, wherein at least one tip mass is attached to a second end of the cantilever, wherein the second end of the cantilever is opposite the first end.

14. Piezoelectric energy harvesting system according to claim 13, wherein a weight of the at least on tip mass is customized.

15. Piezoelectric energy harvesting system according to claim 14, wherein a first tip mass is attached to a tope side of the second end of the cantilever, and wherein a second tip mass is attached to a bottom side of the second end of the cantilever.
